(19) United States
(12) Patent Application Publication
(10) Pub. No.: US 2024/0261880 A1
(43) Pub. Date: Aug. 8, 2024

(54) ELECTRODEPOSITED WIRE FOR SAW WIRE AND METAL WIRE, AND METHOD OF MANUFACTURING ELECTRODEPOSITED WIRE FOR SAW WIRE

(71) Applicant: Panasonic Intellectual Property Management Co., Ltd., Osaka (JP)

(72) Inventors: Tomohiro KANAZAWA, Osaka (JP); Kenshi TSUJI, Osaka (JP); Naoki KOHYAMA, Osaka (JP)

(73) Assignee: Panasonic Intellectual Property Management Co., Ltd., Osaka (JP)

(21) Appl. No.: 18/564,079

(22) PCT Filed: May 31, 2022
(86) PCT No.: PCT/JP2022/022216

§ 371 Date: Nov. 25, 2023

(30) Foreign Application Priority Data
Jun. 11, 2021 (JP) 2021-098313

(51) Int. Cl. B23D 65/00; B23D 61/18; B23D 81/00

(52) U.S. Cl. CPC B23D 65/00; B23D 61/185; B23D 81/00

(57) ABSTRACT

An electrodeposited wire for a saw wire includes a core wire containing tungsten or a tungsten alloy. The electrodeposited wire for a saw wire has a tensile strength of at least 4800 MPa. The electrodeposited wire for a saw wire has a straightness of at least 400 mm per 500 mm in length.

### TECHNICAL FIELD

The present invention relates to an electrodeposited wire for a saw wire and a metal wire, and a method of manufacturing the electrodeposited wire for a saw wire.

### BACKGROUND ART

Patent Literature (PTL) 1 discloses a saw wire including a metal wire containing a tungsten alloy and electrodeposited abrasive particles on the surface of the metal wire.

### CITATION LIST

### Patent Literature

[PTL 1] Japanese Unexamined Patent Application Publication No. 2018-187739

### SUMMARY OF INVENTION

### Technical Problem

The present invention aims to provide, for example, an electrodeposited wire for a saw wire, which can achieve both a high tensile strength and a high level of straightness, and a metal wire for use as its core wire.

### Solution to Problem

An electrodeposited wire for a saw wire according to one aspect of the present invention includes a core wire containing tungsten or a tungsten alloy. The electrodeposited wire for a saw wire has: a tensile strength of at least 4800 MPa; and a straightness of at least 400 mm per 500 mm in length.

A metal wire according to one aspect of the present invention is a metal wire being for use as a core wire of an electrodeposited wire for a saw wire; including a carbon coating layer on a surface of the metal wire; having a tensile strength of at least 4800 MPa; and being wound around a winding frame.

A method of manufacturing an electrodeposited wire for a saw wire according to one aspect of the present invention includes: removing a carbon coating layer from a metal wire containing tungsten or a tungsten alloy and including the carbon coating layer; and electrodepositing abrasive particles on the metal wire after the removing has been performed. The removing and the electrodepositing are performed in series.

### Advantageous Effects of Invention

The present invention can provide, for example, an electrodeposited wire for a saw wire, which can achieve both a high tensile strength and a high level of straightness, and a metal wire for use as its core wire.

### BRIEF DESCRIPTION OF DRAWINGS

FIG. 1 is a schematic cross-sectional view of an electrodeposited wire for a saw wire according to an embodiment.

FIG. 2 is a process chart illustrating a method of manufacturing an electrodeposited wire for a saw wire according to comparative examples.

FIG. 3 is a process chart illustrating a method of manufacturing the electrodeposited wire for a saw wire according to the embodiment.

FIG. 4 is a schematic perspective view of a metal wire to be used as a core wire of the electrodeposited wire for a saw wire according to the embodiment.

FIG. 5 is a schematic cross-sectional view of the metal wire illustrated in FIG. 4.

FIG. 6 is a process chart illustrating a method of manufacturing an electrodeposited wire for a saw wire according to a variation of the embodiment.

### DESCRIPTION OF EMBODIMENTS

The following describes in detail an electrodeposited wire for a saw wire and a metal wire, and a method of manufacturing the electrodeposited wire for a saw wire according to embodiments of the present invention with reference to the drawings. Note that each of the embodiments described below shows a specific example of the present invention. As such, the numerical values, shapes, materials, structural elements, the arrangement and connection of the structural elements, steps, the order of the steps, and so on, shown in the following embodiments are mere examples, and therefore do not limit the present invention. Therefore, among the structural elements in the embodiments described below, structural elements not recited in the independent claims will be described as optional structural elements.

In addition, figures are schematic illustrations and are not necessarily precise depictions. Accordingly, for example, the figures are not necessarily to scale. Moreover, in the figures, structural elements that are essentially the same share like reference signs. Accordingly, duplicate description is omitted or simplified.

Moreover, in the present specification, terms representing relationships between structural elements such as a straight line or perpendicular, terms describing the shapes of structural elements such as circular or cylindrical, and numerical ranges include, not only the precise meanings, but also substantially equal ranges including, for example, a difference of approximately a few or several percent.

### EMBODIMENT

### [Electrodeposited Wire for Saw Wire]

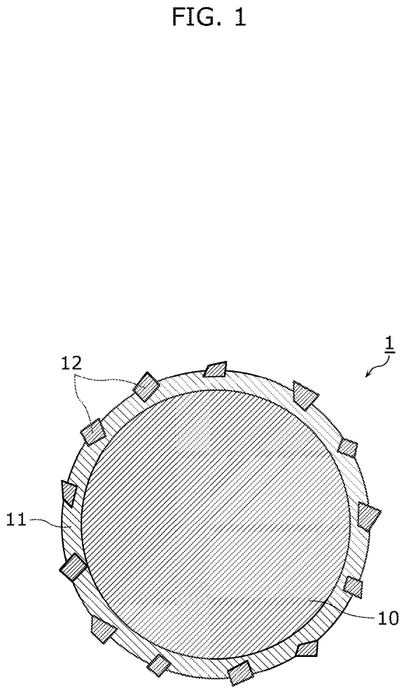

Firstly, a configuration of an electrodeposited wire for a saw wire according to an embodiment will be described with reference to FIG. 1. FIG. 1 is a schematic cross-sectional view of electrodeposited wire 1 for a saw wire according to the present embodiment.

Electrodeposited wire 1 for a saw wire is used as a saw wire to cut an ingot of semiconductor, such as silicon and silicon carbide. For example, silicon wafers can be manufactured by cutting a silicon ingot using electrodeposited wire 1 for a saw wire. Note that objects to be cut with electrodeposited wire 1 for a saw wire are not limited to semiconductor ingots, but include solid products (lumps) made of various solid materials, such as metals, resins, glass, or concrete.

As illustrated in FIG. 1, electrodeposited wire 1 for a saw wire includes core wire 10, plating layer 11, and abrasive particles 12.

Core wire 10 is a metal wire containing tungsten or a tungsten alloy. The tungsten content of core wire 10 is, for example, but not limited to, at least 90 wt %. Note that the tungsten content of core wire 10 may be at least 95 wt %, at least 99 wt %, at least 99.9 wt %, or 99.99 wt %. Note that core wire 10 may include inevitable impurities that cannot be avoided from being mixed during the manufacturing process.

The tungsten alloy is, for example, an alloy containing tungsten (W) and at least one type of metal different from tungsten. An example of metals other than tungsten is rhenium (Re). The rhenium content of core wire 10 containing a rhenium tungsten alloy (ReW) is, for example, but not limited to, at least 0.1 wt % and at most 10 wt %. For example, the rhenium content may be at least 1 wt %, at least 3 wt %, or at least 5 wt %.

When the rhenium content is high, the tensile strength of core wire 10 can be increased. On the other hand, when the rhenium content is too high, it is difficult to thin core wire 10 while maintaining a high tensile strength of core wire 10. Specifically, breakage is more likely to occur, making it difficult to draw core wire 10 in a long length. By lowering the rhenium content and increasing the tungsten content to 90 wt % or more, the workability of core wire 10 can be improved. In addition, by reducing the content of rare and expensive rhenium, it is possible to mass-produce inexpensive core wires 10 in long lengths.

Note that the metal used in the alloy with tungsten may be osmium (Os), ruthenium (Ru), or iridium (Ir). The content of osmium, ruthenium, or iridium is equal to the content of rhenium, for example. In these cases, similar effects can be obtained as in the case of rhenium tungsten alloy. Core wire 10 may contain an alloy of tungsten and at least two types of metals different from tungsten.

Core wire 10 has a substantially circular cross-sectional shape in the cross-section perpendicular to the axis direction of core wire 10. Note that the axis direction is a direction in which core wire 10 extends. The diameter of core wire 10 is substantially constant in the axis direction. The diameter of core wire 10 is, for example, but not limited to, at most 100 μm. The diameter of core wire 10 may be at most 80 μm, at most 60 μm, at most 50 μm, at most 40 μm, at most 30 μm, at most 20 μm, or at most 10 μm.

The diameter of electrodeposited wire 1 for a saw wire decreases as the diameter of core wire 10 decreases. When the diameter of electrodeposited wire 1 for a saw wire is reduced, the cutting allowance of an object to be cut decreases. Therefore, it is possible to reduce a kerf loss of the object to be cut and increase the number of wafers that can be obtained.

Note that the diameter of core wire 10 is, for example, at least 5 μm. This ensures that the cross-sectional area of core wire 10 will not be too small and that the absolute strength of core wire 10 will be within a range available as a saw wire.

Plating layer 11 covers the surface of core wire 10. Specifically, plating layer 11 covers the entire surface of core wire 10 over the entire circumference around an axis of core wire 10. Plating layer 11 is provided to fix abrasive particles 12 thereon by electrodeposition. Plating layer 11 tightly and closely covers at least part of abrasive particles 12.

Plating layer 11 contains nickel, for example. Plating layer 11 may be a plating layer made of a simple substance of nickel or a plating layer made of a nickel alloy. Plating layer 11 may be multi-layered.

Plating layer 11 is formed to have a substantially uniform thickness along the circumference around the axis of core wire 10. The thickness of plating layer 11 is, for example, but not limited to, at most 10 μm. The thickness of plating layer 11 may be at most 5 μm or at most 2 μm. The diameter of electrodeposited wire 1 for a saw wire decreases as the diameter of plating layer 11 decreases. Therefore, it is possible to reduce a kerf loss of an object to be cut. Note that the thickness of plating layer 11 is, for example, at least 1 μm. This makes it possible to hold abrasive particles 12 strong enough.

Abrasive particles 12 are hard particles, and are, for example, particles of diamond or cubic boron nitride (CBN). Abrasive particles 12 are dispersed and provided on the surface of core wire 10. The average particle size of abrasive particles 12 is, for example, at most 10 μm. At least of part of abrasive particles 12 is covered by plating layer 11, thereby abrasive particles 12 are adhered to the 35 surface of core wire 10.

Electrodeposited wire 1 for a saw wire illustrated in FIG. 1 has a tensile strength of at least 4800 MPa. The tensile strength may be at least 5000 MPa, at least 5200 MPa, at least 5500 MPa, or at least 5700 MPa. The tensile strength may be, for example, at most 6000 MPa, but may be more than 6000 MPa. The tensile strength can be measured, for example, in accordance with the tensile test (JIS H 4460 8) of the Japanese Industrial Standard.

Electrodeposited wire 1 for a saw wire is often used while being stretched strongly on a guide roller of a cutting device (wire saw device). Electrodeposited wire 1 for a saw wire rotates along with the guide roller to cut an object to be cut. Therefore, electrodeposited wire 1 for a saw wire can be stretched more strongly on the guide roller as the tensile strength of electrodeposited wire 1 for a saw wire increases, and thus the oscillation width of electrodeposited wire 1 for a saw wire can be reduced. When the oscillation width of electrodeposited wire 1 for a saw wire is reduced, the cutting allowance of the object to be cut decreases. This makes it possible to reduce a kerf loss of the object to be cut.

The straightness of electrodeposited wire 1 for a saw wire is expressed as a natural hanging length per 500 mm in length of electrodeposited wire 1 for a saw wire. Specifically, the straightness (natural hanging length per 500 mm in length) of electrodeposited wire 1 for a saw wire is at least 400 mm. The straightness of electrodeposited wire 1 for a saw wire may be at least 450 mm, at least 475 mm, at least 485 mm, at least 490 mm, or at least 495 mm. The natural hanging length can be measured, for example, in accordance with the straightness test (JIS H 4460 15) of the Japanese Industrial Standard.

Attaching a wire to the guide roller becomes more easier and occurrence of breakage can be reduced as the straightness of the wire increases. In addition, since electrodeposited wire 1 for a saw wire can be stretched straight, the object to be cut can be cut smoothly, and occurrence of breakage during cutting can be reduced.

As described above, electrodeposited wire 1 for a saw wire according to the present embodiment has a tensile strength of at least 4800 MPa and a straightness of at least 400 mm per 500 mm in length. In other words, electrodeposited wire 1 for a saw wire can achieve both a high tensile strength and a high level of straightness.

### [Manufacturing Method]

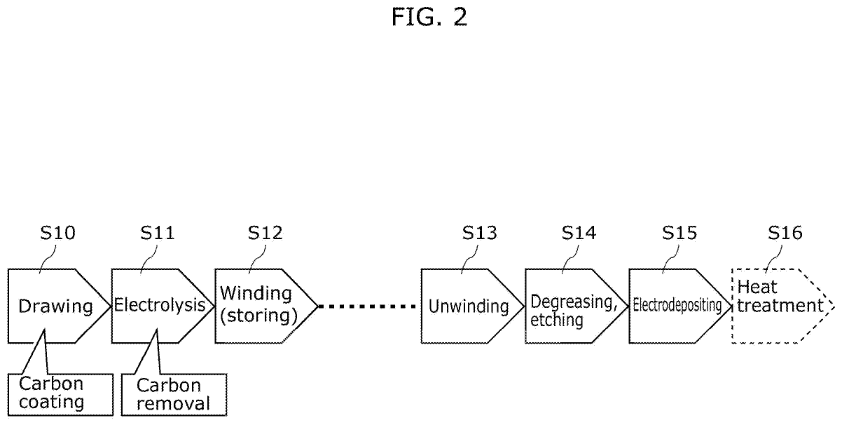

The following describes a method of manufacturing electrodeposited wire 1 for a saw wire according to the present embodiment. Firstly, a method of manufacturing an electrodeposited wire for a saw wire according to comparative examples and its problems will be described with reference to FIG. 2. FIG. 2 is a process chart illustrating a method of manufacturing an electrodeposited wire for a saw wire according to comparative examples.

As illustrated in FIG. 2, firstly, drawing is performed (S10). In the drawing, swaging processing or rolling processing is performed on an ingot containing tungsten or a tungsten alloy to form the ingot into a tungsten wire having a wire shape. The tungsten wire is heated (annealed) and drawn (thinned) using wire drawing dies, while the tungsten wire is being heated. In the drawing, a lubricant including graphite dispersed in water may be used.

The drawing is repeatedly performed using wire drawing dies having different pore diameters until a desired wire diameter is obtained. In the repeating of the drawing, the tungsten wire is heated at a heating temperature lower than the heating temperature used in the immediately preceding drawing. In other words, the heating temperature is gradually lowered. The final heating temperature is, for example, 400° C., which contributes to refinement of crystal grains.

Moreover, in the last drawing, drawing at room temperature without heating is performed. Room temperature is, for example, a temperature in a range of 0° C. to 50° C. An example of room temperature is 30° C. With this, a tungsten wire having a high tensile strength can be obtained. Specifically, a tungsten wire having a tensile strength of at least 4800 MPa can be obtained. The surface of the tungsten wire immediately after drawing is coated with carbon. By including graphite in the lubricant used in this drawing, a stronger film is formed and the tungsten wire slips more smoothly during unwinding of the wire in a later process.

Next, electrolysis is performed (S11). Electrolysis is performed by immersing the tungsten wire and a counter electrode in an electrolyte solution, such as a sodium hydroxide solution, and causing a potential difference between the tungsten wire and the counter electrode. By performing electrolysis, carbon adhered on the surface is removed. Electrolysis also makes it possible to finely adjust the diameter of the tungsten wire.

The electrolyzed tungsten wire is wound around a winding frame (S12). The tungsten wire can be stored and distributed with being wound around the winding frame. Since the tungsten wire can be stored for a certain period of time, the tungsten wire can be used for other purposes, such as mesh, according to demand, in addition to use as a saw wire.

Subsequently, to manufacture an electrodeposited wire for a saw wire, the tungsten wire is unwound from the winding frame (S13). The tungsten wire that is unwound from the winding frame is a tungsten wire that has been electrolyzed. The electrolyzed tungsten wire has poor slip due to the rough surface, and the straightness may decrease when it is unwound. In some cases, the unwinding may break the tungsten wire.

In addition, on the surface of the unwound tungsten wire, an oxidation layer and/or an oil layer of a few or several nanometers is often formed during storage. Therefore, degreasing and/or etching is necessary (S14). Depending on the thickness of the oxidation layer and/or oil layer formed, it is necessary to adjust the degreasing and/or etching conditions, making it difficult to perform degreasing and/or etching under appropriate conditions. If the removal of the oxidation layer and the oil layer is insufficient, the adhesion strength between the wire and the plating layer resulting from electrodeposition will be insufficient.

Electrodeposition is performed on the tungsten wire after the oxidation layer and the oil layer are removed (S15). With this, an electrodeposited wire for a saw wire including a tungsten wire including abrasive particles electrodeposited on the surface is manufactured.

However, the straightness of the electrodeposited wire for a saw wire immediately after electrodeposition is partially deteriorated due to the unwinding (S13). Therefore, in the comparative examples, heat treatment is performed (S16) after electrodeposition. Straightness can be increased by performing heat treatment. However, although the straightness is increased by heat treatment, the tensile strength of the electrodeposited wire for a saw wire is decreased.

Table 1 below shows the diameter, tensile strength, and straightness of electrodeposited wires for saw wires according to Comparative Examples 1 to 5. In Comparative Examples 1 and 4, heat treatment (S16) is not performed. In Comparative Examples 2, 3, and 5, heat treatment (S16) is performed. The heating temperature used in Comparative Examples 2 and 5 is the same, and the heating temperature used in Comparative Example 3 is different from the temperature used in Comparative Examples 2 and 5.

TABLE 1

| | | Tensile | Temper- | Tensile | |
|---|---|---|---|---|---|
| | | strength | ature | strength | Straight- |
| | | before heat | of heat | after heat | ness |
| | Diameter | treatment | treatment | treatment | [mm/ |
| | [μm] | [MPa] | [° C.] | [MPa] | 500 mm] |
| Compar- | 35 | 5120 | — | 5120 | 390 |
| ative | | | | | |
| Example 1 | | | | | |
| Compar- | 35 | 5120 | 800 | 4520 | 480 |
| ative | | | | | |
| Example 2 | | | | | |
| Compar- | 35 | 5120 | 1000 | 3950 | 490 |
| ative | | | | | |
| Example 3 | | | | | |
| Compar- | 35 | 4000 | — | 4000 | 390 |
| ative | | | | | |
| Example 4 | | | | | |
| Compar- | 35 | 4000 | 800 | 4000 | 480 |
| ative | | | | | |
| Example 5 | | | | | |

In all Comparative Examples 1-3, the tungsten wire immediately before winding had a straightness of 490 mm and a tensile strength of 5120 MPa. As shown in the result of Comparative Example 1, when heat treatment (S16) is not performed, the tensile strength remains high while the straightness decreases. On the other hand, as shown in the results of Comparative Examples 2 and 3, the straightness is increased by performing heat treatment (S16). However, the tensile strength is decreased by heat treatment. The straightness increases as the temperature of the heat treatment increases, but the tensile strength decreases greatly.

Note that, when the tensile strength is 4000 MPa, the straightness is increased by performing heat treatment (S16), as shown in the results of Comparative Examples 4 and 5. That is to say, the straightness of a tungsten wire having a tensile strength less than 4800 MPa can be increased by heat treatment. This is because primary recrystallization is unlikely to occur in heat treatment at approximately 800° C.

On the other hand, in high-strength tungsten wire having a tensile strength of 4800 MPa or more, the tensile strength is increased because many grain boundaries and subgrain boundaries are present. In a tungsten wire in which many grain boundaries and subgrain boundaries are present, the primary recrystallization occurs when the tungsten wire is heated at approximately 800° C. Therefore, the tensile strength cannot be maintained high. For this reason, a decrease in tensile strength occurs, as shown in the results of Comparative Examples 2 and 3.

Accordingly, with the manufacturing method according to the comparative examples, a high tensile strength and a high level of straightness cannot be both achieved. In particular, in order to achieve a high tensile strength of 4800 MPa or more, heat treatment to increase straightness cannot be performed.

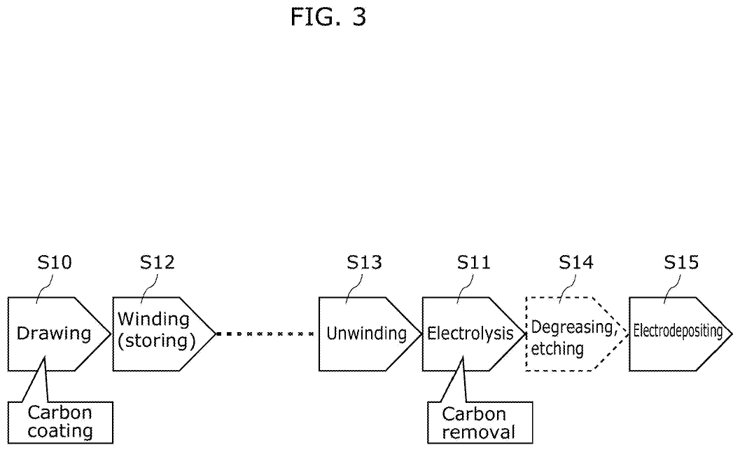

In contrast, with the method of manufacturing electrodeposited wire 1 for a saw wire according to the present embodiment, a high tensile strength and a high level of straightness can both be achieved. The following describes a method of manufacturing electrodeposited wire 1 for a saw wire according to the present embodiment, with reference to FIG. 3. FIG. 3 is a process chart illustrating a method of manufacturing electrodeposited wire 1 for a saw wire according to the present embodiment.

As illustrated in FIG. 3, firstly, drawing is performed (S10). The drawing is the same as the drawing illustrated in FIG. 2. Next, in the present embodiment, winding (S12) is performed without electrolysis (S11). In other words, a metal wire whose surface is covered with carbon is wound around a winding frame without removing carbon. The metal wire having a carbon coating layer on its surface can be stored and distributed with being wound around the winding frame. Since the metal wire can be stored for a certain period of time, the metal wire can be processed (specifically, electrodeposited) to be used as a saw wire at a necessary timing.

Subsequently, to manufacture electrodeposited wire 1 for a saw wire, the metal wire is unwound from the winding frame (S13). The metal wire unwound from the winding frame is a metal wire including a carbon coating layer on the surface. Due to the formation of the carbon coating layer, the surface of the metal wire is smooth. Therefore, this inhibits a decrease in the straightness of the metal wire when it is unwound. This also inhibits the occurrence of breakage of the metal wire due to unwinding. In other words, the unwound metal wire can maintain the tensile strength equivalent to the tensile strength of the metal wire immediately before it is wound around the winding frame.

Next, electrolysis is performed on the unwound metal wire (S11). The specific conditions for electrolysis are the same as the conditions for electrolysis (S11) illustrated in FIG. 2. By performing electrolysis, the carbon coating layer on the surface is removed. In other words, electrolysis is an example of removing of the carbon coating layer of the metal wire. In addition, fine adjustment of the diameter is performed.

Next, degreasing and/or etching is performed as necessary (S14). The metal wire immediately after electrolysis (i.e., the core wire from which the surface coating layer has been removed) has substantially no oxidation layer and/or oil layer formed thereon. Therefore, degreasing and/or etching is not necessary. Even in the case of degreasing and/or etching, it is easy to adjust the conditions. Therefore, the surface of the core material can be easily brought to a clean state (without an oil layer and/or an oxidation layer).

Next, electrodeposition is performed on the core material (S15). The specific conditions for electrodeposition are the same as the conditions for electrodeposition (S15) illustrated in FIG. 2. With this, electrodeposited wire 1 for a saw wire including abrasive particles 12 electrodeposited on the surface of core wire 10 by plating layer 11 as illustrated in FIG. 1 is manufactured.

As described above, in the present embodiment, electrolysis (S11) and electrodeposition (S15) are performed in series. “Performed in series” means to perform electrolysis and electrodeposition successively without an interval of a sufficient amount of time. A sufficient amount of time is, for example, one hour. At least between electrolysis (S11) and electrodeposition (S15), the wire is not would around the winding frame and not stored for a predetermined period. For example, electrolysis (S11) and electrodeposition (S15) are performed successively in-line. As described above, since the surface contamination of the core wire is inhibited by performing electrolysis and electrodeposition in series, the adhesion strength between core wire 10 and plating layer 11 increases, and removal of abrasive particles 12 that are electrodeposited can be inhibited.

Moreover, in the present embodiment, the metal wire on which a carbon coating layer is formed is wound around and unwound from the winding frame. Therefore, a decrease in straightness at the time of unwinding is inhibited. For this reason, after electrodeposition, heat treatment (S16) to increase straightness is not necessary. Since heat treatment is not performed, a decrease in tensile strength is inhibited. In other words, electrodeposited wire 1 for a saw wire can achieve both a high tensile strength and a high level of straightness.

Table 2 below shows the diameter, tensile strength, and straightness of each of electrodeposited wires 1 for saw wires according to Working Examples 1 and 2.

TABLE 2

| | | | Straight- |
|---|---|---|---|
| | | Tensile | ness |
| | Diameter | strength | [mm/ |
| | [μm] | [MPa] | 500 mm] |
| Working | 35 | 5130 | 470 |
| Example 1 | | | |
| Working | 42 | 4970 | 430 |
| Example 2 | | | |

In Working Examples 1 and 2, the tensile strength and straightness were almost the same at the time of immediately after drawing (S10), immediately after unwinding (S13), and immediately after electrodeposition (S15). In other words, the tensile strength and the straightness of the metal wire obtained by drawing are almost unchanged after winding and unwinding. Similarly, the tensile strength and the straightness of the metal wire after unwinding remain almost unchanged after electrolysis and electrodeposition. In the present embodiment, since the heat treatment is not performed on electrodeposited wire 1 for a saw wire, both a high tensile strength and a high level of straightness can be maintained and achieved.

### [Metal Wire to be Used as Core Wire of Electrodeposited Wire for Saw Wire]

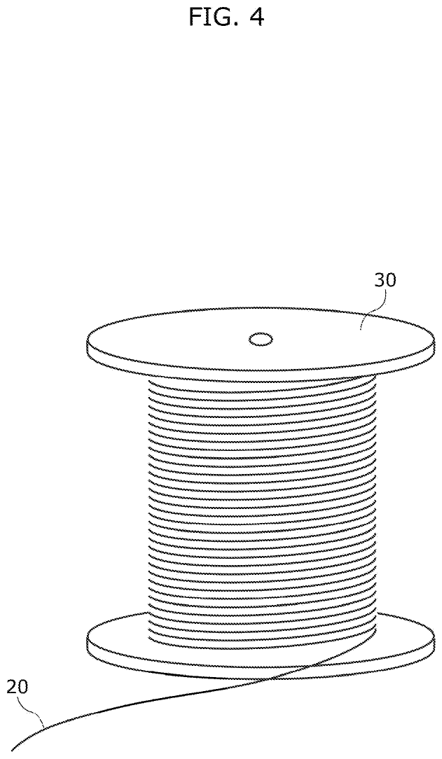

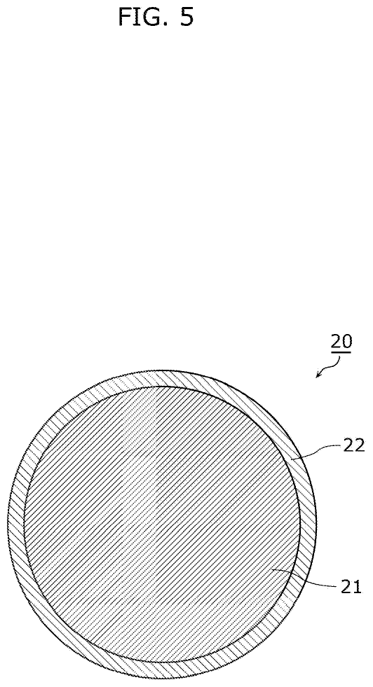

The metal wire wound in step S12 in FIG. 3 will be described below with reference to FIG. 4 and FIG. 5.

FIG. 4 is a schematic perspective view of metal wire 20 to be used as a core wire of electrodeposited wire 1 for a saw wire according to the present embodiment. FIG. 5 is a schematic cross-sectional view of metal wire 20 illustrated in FIG. 4.

As illustrated in FIG. 4, metal wire 20 is wound around bobbin 30. Bobbin 30 is an example of a winding frame. Bobbin 30 includes a cylindrical (or columnar) core material and a disk-shaped member provided on both ends of the core material with a diameter greater than the outer diameter of the core material. Bobbin 30 is made of galvanized steel, for example, but may be made of other metal or resin.

For example, the outer diameter of the core material is at least 100 mm and at most 300 mm and the height is at least 200 mm and at most 300 mm, but the present invention is not limited to this example. When the outer diameter of the core material is large, the curve of metal wire 20 becomes gentle, and the bending stress applied to metal wire 20 can be reduced. The distortion occurring in metal wire 20 is reduced, and a decrease in straightness at the time of unwinding can be inhibited. Moreover, when the outer diameter of core material is small, metal wire 20 can be kept compact. Therefore, metal wire 20 can be stored in a space-saving manner, and can be easily transported. As an example, the outer diameter of the core material is 150 mm.

The total length of metal wire 20 wound around bobbin 30 is, for example, but not limited to, at least 50 km and at most 300 km. Metal wire 20 has a total length in the order of kilometer. Note that the winding frame on which metal wire 20 is wound does not have to be bobbin 30. A winding frame called a reel, spool, or drum may be used.

As illustrated in FIG. 5, metal wire 20 includes core wire 21 and coating layer 22. Core wire 21 is substantially the same as core wire 10 of electrodeposited wire 1 for a saw wire illustrated in FIG. 1. Since the diameter may decrease when electrolysis (S11 in FIG. 3) is performed, core wire 21 may have a larger diameter than core wire does.

Coating layer 22 is a carbon coating layer. That is to say, coating layer 22 contains carbon. Specifically, coating layer 22 contains carbon and an oxide of tungsten. Coating layer 22 is formed with a substantially uniform thickness along the circumference around the axis of core wire 21. The thickness of coating layer 22 is, for example, but not limited to, at most 0.2 μm.

Metal wire 20 has a substantially circular cross-sectional shape in the cross-section perpendicular to the axis direction of metal wire 20. The diameter of metal wire 20 is substantially constant along the axis direction. The diameter of metal wire 20 is, for example, but not limited to, at most 100 μm. The diameter of metal wire 20 may be at most 80 μm, at most 60 μm, at most 50 μm, at most 40 μm, at most 30 μm, at most 20 μm, or at most 10 μm.

The diameter of electrodeposited wire 1 for a saw wire decreases as the diameter of metal wire 20 decreases. When the diameter of electrodeposited wire 1 for a saw wire is reduced, the cutting allowance of the object to be cut decreases. Therefore, it is possible to reduce a kerf loss of the object to be cut and increase the number of wafers that can be obtained.

Metal wire 20 has a tensile strength of at least 4800 MPa. The tensile strength may be at least 5000 MPa, at least 5200 MPa, at least 5500 MPa, or at least 5700 MPa. The tensile strength may be, for example, at most 6000 MPa, but may be more than 6000 MPa.

### [Effects, Etc.]

As described above, electrodeposited wire 1 for a saw wire according to the present embodiment includes core wire 10 containing tungsten or a tungsten alloy. Electrodeposited wire 1 for a saw wire has a tensile strength of at least 4800 MPa. Electrodeposited wire 1 for a saw wire has a straightness of at least 400 mm per 500 mm in length.

This makes it possible to provide electrodeposited wire 1 for a saw wire that can achieve both a high tensile strength and a high level of straightness.

Moreover, metal wire 20 according to the present embodiment is for use as a core wire of electrodeposited wire 1 for a saw wire. Metal wire 20 includes a carbon coating layer on a surface of metal wire 20. Metal wire 20 has a tensile strength of at least 4800 MPa. Metal wire 20 is wound around a winding frame.

This makes it possible to provide metal wire 20 that can be used as core wire 10 of electrodeposited wire 1 for a saw wire that can achieve both a high tensile strength and a high level of straightness.

Moreover, for example, metal wire 20 has a diameter of at most 100 μm.

With this, when metal wire 20 is used as core wire 10 of electrodeposited wire 1 for a saw wire, a kerf loss of an object to be cut can be reduced because the diameter is small.

Moreover, a method of manufacturing electrodeposited wire 1 for a saw wire according to the present embodiment includes: removing a carbon coating layer from metal wire 20 containing tungsten or a tungsten alloy and including the carbon coating layer; and electrodepositing abrasive particles on metal wire 20 after the removing has been performed. The removing and the electrodepositing are performed in series. At this time, for example, in the removing, the carbon coating layer is removed by performing electrolysis on metal wire 20.

With this, electrodeposited wire 1 for a saw wire that can achieve both a high tensile strength and a high level of straightness can be manufactured. Moreover, since impurities on the surface of core wire 10 are sufficiently reduced by performing removing and electrodepositing in series, the adhesion strength between core wire and plating layer 11 increases. The high adhesion strength between core wire 10 and plating layer 11 inhibits removal of abrasive particles 12 and inhibits decrease in sharpness when an object to be cut is cut.

Moreover, for example, the method of manufacturing electrodeposited wire 1 for a saw wire includes unwinding metal wire from a winding frame around which metal wire 20 is wound. In the removing, the carbon coating layer of metal wire 20 that has been unwound from the winding frame is removed. Winding of metal wire 20 around a winding frame is not performed between the removing and the electrodepositing.

With this, electrodeposited wire 1 for a saw wire that can achieve both a high tensile strength and a high level of straightness can be manufactured. By omitting the winding and the unwinding between the removing and the electrodepositing, adhesion of an oxide layer and/or an oil layer to the surface can be inhibited.

### [Others]

The foregoing has described the electrodeposited wire for a saw wire and the metal wire to be used as its core wire, and the method of manufacturing the electrodeposited wire for a saw wire according to the present invention, based on the embodiment and so on, but the present invention should not be limited to the embodiment described above.

For example, in the above embodiment, the tungsten wire may be doped with a minute amount of potassium, etc. Doped potassium is present at the crystal grain boundaries of tungsten. The potassium (K) content is, for example, at most 0.010 wt %. Potassium doped tungsten wire can also achieve a tungsten wire having a higher tensile strength than a general tensile strength of a piano wire, as with the tungsten alloy wire. Similar effects can be obtained not only with oxides of potassium but also with oxides of other substances such as cerium or lanthanum.

In addition, for example, the present invention can be implemented as a tungsten product including a winding frame, such as bobbin 30, and metal wire 20 wound around the winding frame.

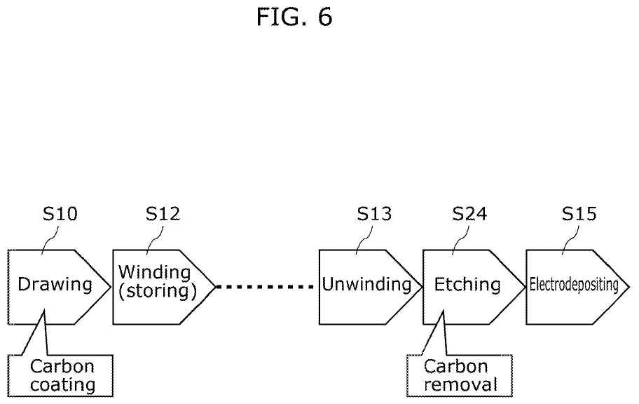

In addition, for example, the electrolysis (S11) does not necessarily need to be performed. FIG. 6 is a process chart illustrating a method of manufacturing electrodeposited wire 1 for a saw wire according to a variation of the embodiment.

As illustrated in FIG. 6, the surface of the metal wire unwound from the winding frame is etched without performing the electrolysis (S24). Etching is performed, for example, with an aqueous solution of sodium hydroxide. By performing etching, the carbon coating layer is removed.

After etching, electrodeposition is performed on the core material (S15). The specific conditions for electrodeposition are the same as the conditions for electrodeposition (S15) illustrated in FIG. 2. Even in the case of the manufacturing method illustrated in FIG. 6, as with the embodiment, electrodeposited wire 1 for a saw wire having a high tensile strength and a high level of straightness can be manufactured.

As described above, in the manufacturing method according to the variation, the removing of the carbon coating layer and the electrodepositing are performed in series. The meaning of “performed in series” is the same as the meaning stated in the embodiment. Since the surface contamination of the core wire is inhibited by performing the removing of the carbon coating layer and the electrodepositing in series, the adhesion strength between core wire 10 and plating layer 11 increases, and removal of abrasive particles 12 can be inhibited.

Additionally, embodiments arrived at by those skilled in the art making various modifications to the above embodiment, as well as embodiments arrived at by combining structural elements and functions described in the above embodiment in any manner without materially departing from the teachings of the present invention are intended to be included within the scope of the present invention.

### REFERENCE SIGNS LIST

1 electrodeposited wire for a saw wire
10, 21 core wire
20 metal wire
22 coating layer
30 bobbin (winding frame)

1. An electrodeposited wire for a saw wire comprising:
a core wire containing tungsten or a tungsten alloy, wherein the electrodeposited wire for a saw wire has:
a tensile strength of at least 4800 MPa; and
a straightness of at least 400 mm per 500 mm in length.

2. A metal wire characterized by:
being for use as a core wire of an electrodeposited wire for a saw wire;
including a carbon coating layer on a surface of the metal wire;
having a tensile strength of at least 4800 MPa; and
being wound around a winding frame.

3. The metal wire according to claim 2, wherein
the metal wire has a diameter of at most 100 μm.

4. A method of manufacturing an electrodeposited wire for a saw wire, the method comprising:
removing a carbon coating layer from a metal wire containing tungsten or a tungsten alloy and including the carbon coating layer; and
electrodepositing abrasive particles on the metal wire after the removing has been performed, wherein
the removing and the electrodepositing are performed in series.

5. The method of manufacturing an electrodeposited wire for a saw wire according to claim 4, wherein
in the removing, the carbon coating layer is removed by electrolyzing the metal wire.

6. The method of manufacturing an electrodeposited wire for a saw wire according to claim 4, further comprising:
unwinding the metal wire from a winding frame around which the metal wire is wound, wherein
in the removing, the carbon coating layer of the metal wire that has been unwound from the winding frame is removed, and
winding of the metal wire around a winding frame is not performed between the removing and the electrodepositing.
